(19) United States
(12) Patent Application Publication
(10) Pub. No.: US 2024/0291505 A1
(43) Pub. Date: Aug. 29, 2024

(54) PERFECTLY BALANCED ERROR CODE CORRECTION WITHOUT CORRECTION POWER INCREASE

(71) Applicant: Micron Technology, Inc., Boise, ID (US)

(72) Inventor: Christophe Vincent Antoine Laurent, Agrate Brianza (MB) (IT)

(21) Appl. No.: 18/443,883

(22) Filed: Feb. 16, 2024

Related U.S. Application Data
(60) Provisional application No. 63/486,562, filed on Feb. 23, 2023.

(51) Int. Cl. H03M 13/15; H03M 13/00; H03M 13/11

(52) U.S. Cl. CPC H03M 13/1575; H03M 13/1128; H03M 13/6577

(57) ABSTRACT

In some aspects, the techniques described herein relate to a method including: receiving a standard error code correction (ECC) matrix, the standard ECC matrix including a portion for checking a payload and a portion for checking a parity of the payload; and extending the ECC matrix to form an extended matrix by adding a plurality of rows and a plurality of columns to form an upper matrix and a lower matrix, wherein the plurality of rows and columns include at least one all zero portion, at least one portion for checking a quantized Knuth (QK) index, and a portion for checking a parity of the QK index.

### CROSS-REFERENCE TO RELATED APPLICATION

This application claims the benefit of U.S. Prov. Appl. No. 63/486,562, filed Feb. 23, 2023 and incorporated by reference in its entirety.

### TECHNICAL FIELD

At least some embodiments disclosed herein relate to memory systems in general and, more particularly but not limited to, techniques for balancing and performing error correction on codewords stored in such memory devices.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

A memory device can include a memory integrated circuit having one or more arrays of memory cells formed on an integrated circuit die of semiconducting material. A memory cell is the smallest unit of memory that can be individually used or operated upon to store data. In general, a memory cell can store one or more bits of data.

Different types of memory cells have been developed for memory integrated circuits, such as random-access memory (RAM), read-only memory (ROM), dynamic random access memory (DRAM), static random access memory (SRAM), synchronous dynamic random access memory (SDRAM), phase change memory (PCM), magneto random access memory (MRAM), negative-or (NOR) flash memory, electrically erasable programmable read-only memory (EEPROM), flash memory, etc.

Some integrated circuit memory cells are volatile and require power to maintain data stored in the cells. Examples of volatile memory include Dynamic Random-Access Memory (DRAM) and Static Random-Access Memory (SRAM).

Some integrated circuit memory cells are non-volatile and can retain stored data even when not powered. Examples of non-volatile memory include flash memory, Read-Only Memory (ROM), Programmable Read-Only Memory (PROM), Erasable Programmable Read-Only Memory (EPROM) and Electronically Erasable Programmable Read-Only Memory (EEPROM) memory, etc. Flash memory includes negative-and (NAND) type flash memory or a negative-or (NOR) type flash memory. A NAND memory cell is based on a NAND logic gate; and a NOR memory cell is based on a NOR logic gate.

Cross-point memory (e.g., 3D XPoint memory) uses an array of non-volatile memory cells. The memory cells in cross-point memory are transistor-less. Each of such memory cells can have a selector device and optionally a phase-change memory device that are stacked together as a column in an integrated circuit. Memory cells of such columns are connected in the integrated circuit via two layers of wires running in directions that are perpendicular to each other. One of the two layers is above the memory cells; and the other layer is below the memory cells. Thus, each memory cell can be individually selected at a cross point of two wires running in different directions in two layers. Cross point memory devices are fast and non-volatile and can be used as a unified memory pool for processing and storage.

### BRIEF DESCRIPTION OF THE DRAWINGS

The embodiments are illustrated by way of example and not limitation in the figures of the accompanying drawings in which like references indicate similar elements.

FIG. 1 is a diagram illustrating a quantized Knuth transformation.

FIG. 2 is a block diagram illustrating a decoding process using a specialized error correction code matrix.

FIG. 3 is a flow diagram illustrating a method for decoding a codeword and processing a syndrome according to some of the disclosed embodiments.

FIG. 4 is a block diagram illustrating a memory system according to some embodiments of the disclosure.

FIG. 5 is a block diagram illustrating a computing device showing an example of a client or server device used in the various embodiments of the disclosure.

### DETAILED DESCRIPTION

The disclosed embodiments relate to performing error correction on codewords stored in a memory device or similar type of storage device. The disclosed embodiments utilize an extended error code correction (ECC) matrix that exploits properties of codewords balanced using a quantized Knuth (QK) procedure.

In some aspects, the techniques described herein relate to a method including: receiving a standard error code correction (ECC) matrix, the standard ECC matrix including a portion for checking a payload and a portion for checking a parity of the payload; and extending the ECC matrix to form an extended matrix by adding a plurality of rows and a plurality of columns to form an upper matrix and a lower matrix, wherein the plurality of rows and columns include at least one all zero portion, at least one portion for checking a quantized Knuth (QK) index, and a portion for checking a parity of the QK index.

In some aspects, the techniques described herein relate to a method, wherein the at least one all zero portion includes three all zero portions, wherein a first all zero portion and a second all zero portion are included in the upper matrix and a third all zero portion is included in the lower matrix.

In some aspects, the techniques described herein relate to a method, wherein the at least one portion for checking a QK index includes an upper portion for checking the QK index in the upper matrix and a lower portion for checking the QK index in the lower matrix.

In some aspects, the techniques described herein relate to a method, wherein the portion for checking a parity of the QK index is included in the upper matrix.

In some aspects, the techniques described herein relate to a method, wherein the extended matrix is of the form:

$$[ \begin{matrix}All {0}_{1} & QKU & All {0}_{2} & QKP \\ UD & QKL & UDP & All {0}_{3}\end{matrix} ] ,$$

where All0₁ represents the first all zero portion, All0₂ represents the second all zero portion, All0₃ represents the third all zero portion, QKU represents the upper portion for checking the QK index, QKL represents the lower portion for checking the QK index, QKP represents the portion for checking a parity of the QK index, UD represents the portion for checking the payload and UDP represents the portion for checking a parity of the payload and the QK index.

In some aspects, the techniques described herein relate to a method, further including inputting a codeword into the extended matrix to generate a syndrome, the codeword including user data, a QK index, and parity bits, the syndrome including an upper portion generated based on the QK index and parity bits associated with the QK index and a lower portion generated using the user data, the QK index, and parity bits associated with the user data.

In some aspects, the techniques described herein relate to a method including: inserting a codeword into a parity check matrix to obtain a syndrome, the codeword including a payload, a quantized Knuth (QK) index, and parity bits, the syndrome including an upper syndrome and a lower syndrome; determining, based on the upper syndrome and lower syndrome, that an error is present in the QK index; iteratively updating the QK index to generate new codewords; inserting the new codewords into the parity check matrix until an error is detected only in the payload or in a portion of the parity bits associated with the payload; correcting the error; inverting packets of the payload based on the corrected QK index; and returning a corrected payload.

In some aspects, the techniques described herein relate to a method, further including generating the QK index by generating an all-zero value.

In some aspects, the techniques described herein relate to a method, wherein the QK index includes a one-hot encoded packet position relative to a number of packets that were inverted.

In some aspects, the techniques described herein relate to a method, wherein the inverted packets include parity bits and QK index bits.

In some aspects, the techniques described herein relate to a method, wherein determining, based on the upper syndrome and lower syndrome, that an error is present in the QK index includes: determining that the syndrome includes multiple non-zero values; determining that the upper syndrome contains non-zero values; and determining that the error is not solely in the QK index. 12.

In some aspects, the techniques described herein relate to a method, wherein iteratively updating the QK index to generate new codewords includes iterating through a series of one-hot encoded values starting at one.

In some aspects, the techniques described herein relate to a method, wherein determining that an error is only in the payload or in a portion of the parity bits associated with the payload includes determining that the upper syndrome contains all zeros.

In some aspects, the techniques described herein relate to a method including: receiving a payload and a parity portion; generating a first quantized Knuth (QK) index, the first QK index including a one-hot encoded zero value; adding the QK index to the payload and parity portion to generate a codeword; inserting the codeword into a parity check matrix to generate a syndrome, the syndrome including an upper syndrome and lower syndrome; and correcting the codeword based on contents of the upper syndrome and lower syndrome.

In some aspects, the techniques described herein relate to a method, wherein correcting the codeword based on contents of the upper syndrome and lower syndrome includes determining that the syndrome contain all zeros and returning the codeword.

In some aspects, the techniques described herein relate to a method, wherein correcting the codeword based on contents of the upper syndrome and lower syndrome includes determining that the syndrome contains a single non-zero value, correcting an error in the parity portion using an ECC1 engine, and returning a corrected payload.

In some aspects, the techniques described herein relate to a method, wherein correcting the codeword based on contents of the upper syndrome and lower syndrome includes determining that the syndrome includes multiple non-zero values and that the upper syndrome contains all zero values and correcting one or more errors in the payload or parity portion and returning a corrected payload.

In some aspects, the techniques described herein relate to a method, wherein correcting the codeword based on contents of the upper syndrome and lower syndrome includes determining that the syndrome includes multiple non-zero values and that the upper syndrome contains the non-zero values, correcting an error in the QK index to obtain a corrected QK index, inverting a subset of the codeword based on the corrected QK index, and returning a corrected payload.

In some aspects, the techniques described herein relate to a method, wherein correcting the codeword based on contents of the upper syndrome and lower syndrome includes determining that the syndrome includes multiple non-zero values, that the lower syndrome contains at least one non-zero value, and the upper syndrome contains at least one non-zero value and iteratively updating the QK index to generate new codewords.

In some aspects, the techniques described herein relate to a method, further including: inserting the new codewords into the parity check matrix until an error is detected only in the payload or bits of the parity portion associated with the payload; correcting the error; and returning a corrected payload.

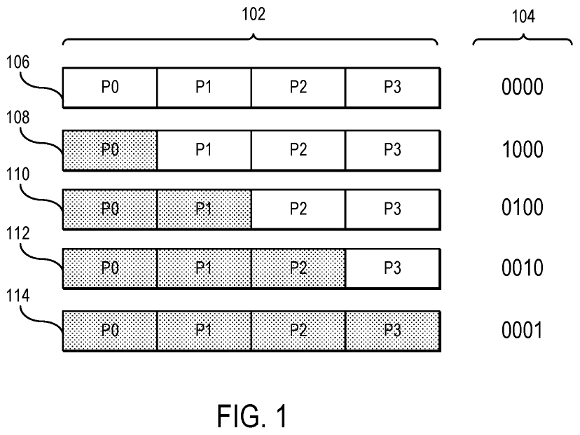

FIG. 1 is a diagram illustrating a QK transformation.

In a QK transformation, a given payload is quantized into packets. For example, the payload 102 in FIG. 1 is quantized into four packets: P0, P1, P2, and P3. In general, the packets will have the same length, and one or more may be zero-padded if the payload is not divisible by the packet length. In some implementations, the packet size may be selected based on the properties of an ECC. For example, a Bose-Chaudhuri-Hocquenghem (BCH) code that can correct up to two errors may have a Hamming distance of five. In this scenario, a packet size equal to or larger than the Hamming distance of five may be used.

The purpose of a QK transformation is to balance the ones and zeroes in the payload by sequentially inverting the bits of packets until the ratio of ones to zeroes meets an error margin. To do this, the transformation starts with an uninverted payload 106. First, the QK algorithm inverts packet P0 and checks the resulting payload 108. If the ratio of zeros to ones of the payload 108 does not meet the desired threshold, the algorithm inverts the next packet, P1, resulting in packets P0 and P1 both being inverted in the payload 110. If the ratio of zeros to ones of payload 110 does not meet the desired threshold, the algorithm continues similarly, inverting packet P2 to obtain payload 112, inverting packet P3 to obtain payload 114, etc.

As soon as the algorithm determines that the ratio of a payload meets the desired threshold, the algorithm ends and outputs a position. This position represents the last inverted packet in the payload and is illustrated as a one-hot encoding 104. Thus, as illustrated, the bits “0000” indicate no packets were inverted, the bits “1000” indicate P0 was inverted, “0100” indicates packets P0 and P1 were inverted, “0010” indicates P0 through P2 were inverted, etc.

Notably, the use of an error margin or threshold is needed since the ratio of ones to zeroes may not be precisely 1:1. Thus, the threshold will define a tolerance (e.g., 1:1.25) that may be used to terminate the algorithm.

When a system that employs a QK algorithm writes the payload, it writes the inverted bits. Thus, payload 110 includes inverted bits for P0 and P1 when written, despite corresponding to the original payload 106. For this reason, the QK index (represented in one-hot encoding 104) should also be stored. This is because a read algorithm must invert P0 and P1 of payload 110 to obtain payload 106. To do this, it must be aware of which packets were flipped. Since the QK algorithm successively inverts packets, storing the identity of the last-inverted packet would be sufficient.

Balancing the number of ones and zeros in a payload in a NAND flash device can improve the reliability and longevity of the device. In NAND flash memory, data is stored by creating and disrupting electrical charges on a memory cell. Further, in some types of NAND Flash devices, balancing will improve the reliability of sensing technologies used in such devices. Additionally, balanced payloads can help improve the efficiency of error correction algorithms, which can further enhance the reliability and performance of the device. Further, since packets are selected based on the Hamming distance of the ECC code, coherency between parity bits and the QK-processed payload is maintained. Notably, in the following examples, it may be presumed that an ECC algorithm is invariant, in that coherency is maintained regardless of whether packet bits are inverted. That is, the ECC algorithm will produce the same parity bit(s) for a packet or its inverse.

In some systems, QK index data is not persisted in memory. For example, if the QK index is stored in a one-hot encoding, during read operations, the QK index data could be presumed to be all zeros, and the ECC power increased to detect the error (if any) in the QK index data. Since a one-hot encoding uses only one bit, the increased ECC power will be able to re-create the QK index encoding, at the expense of more complex and time-consuming processing.

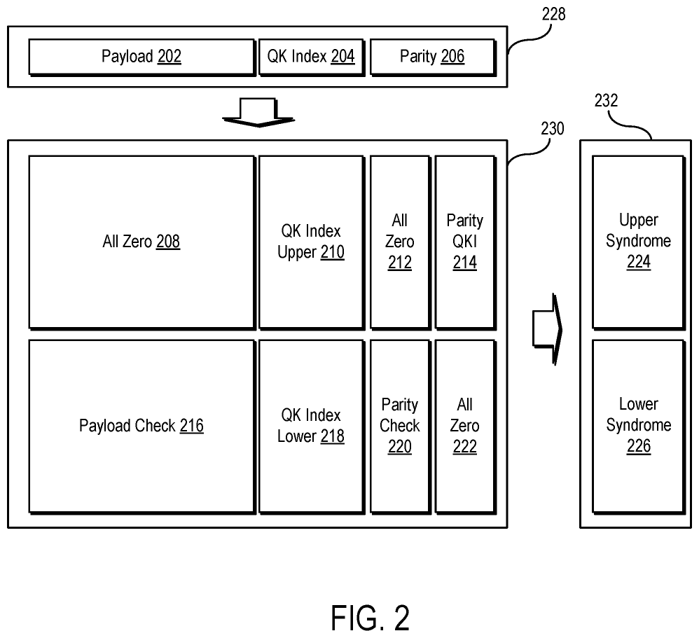

FIG. 2 is a block diagram illustrating a decoding process using a specialized error correction code (ECC) matrix.

In the illustrated implementation, a codeword 228 can be inserted into an ECC engine (not illustrated in FIG. 2, but illustrated elsewhere). The ECC engine stores a parity check matrix 230. In brief, the ECC engine will compute a syndrome 232 using the codeword 228 and the parity check matrix 230. The parity check matrix 230 represents a series of linear relations (i.e., coefficients of parity check equations) defining an ECC code. The specifics of computing a syndrome are not described in detail herein and any accepted way of computing a syndrome using a parity check matrix (e.g., performing a matrix multiplication between the parity check matrix 230 and the codeword 228 to generate syndrome 232). If the syndrome is all zero values, the codeword 228 includes no errors. By contrast, if the syndrome includes non-zero values (i.e., ones), one or more errors are present within the codeword 228.

In the illustrated implementation, a codeword 228 includes three portions: a payload 202, a quantized Knuth index (QK index 204), and a parity portion 206. In some implementations, the payload 202 and parity 206 may be read from a memory device while QK index 204 may be synthesized and not stored in the memory device.

The payload 202 may include any type of user data and the specific content of payload 202 is not intended to be limiting. Generally, payload 202 will include binary data of a given length. As one continuing example, the payload 202 may comprise 128 bits of binary data.

The QK index 204 may comprise an encoded QK index. Details of generating a QK index are described in FIG. 1 and not repeated herein. The QK index 204 may be encoded using a one-hot coding scheme, a thermometrical coding scheme, a binary coding scheme, a Gray coding scheme, or similar type of coding scheme. For example, the one—hot coding value of “0000” may indicate no inversions were made while the value of “1000” may indicate that all packets of payload 102 were inverted. Reference is made to FIG. 1 for further details on the QK algorithm.

The parity portion 206 may comprise a set of parity bits computed using a generator matrix. As with other ECCs, the generator matrix may comprise the matrix inverse of parity check matrix 230, the specific details of such a matrix are not expanded upon herein for the sake of brevity. The specific size of the parity portion 206 may be configured based on the needs of the system. In some implementations, the ECC associated with parity check matrix 230 may comprise a Bose-Chaudhuri-Hocquenghem (BCH) code that can include a configurable number of parity bits. In some implementations, the specific ECC code may comprise an ECC1 code (i.e., a code that can correct a single error).

The illustrated parity check matrix 230 represents an extended parity check matrix. As one example, if codeword 228 included only payload 202 and parity portion 206, a standard parity check matrix may only include a payload check portion 216 and parity check portion 220. These two portions combined would form a standard parity check matrix for a standard codeword. However, since the codeword 228 includes QK index 204, this standard parity check matrix is expanded to include additional coefficients for QK index 204 (e.g., QK index lower 218). Further, as will discussed, additional rows are added to the parity check matrix in the form of an upper parity check matrix portion that includes an all zero portion 208, QK index upper 210, all zero portion 212, and a QK parity portion 214. Herein, all zero portion 208, QK index upper 210, all zero portion 212, and QK parity portion 214 are collectively referred to as the “upper matrix” while payload check portion 216, QK index lower 218, and parity check portion 220 are collectively referred to as the “lower matrix.”

The specific contents of QK index upper 210, QK parity portion 214, payload check portion 216, QK index lower 218, and parity check portion 220 will comprise coefficients based on the underlying ECC parity check equations. The specific values of the matrix are not limiting. The contents of all zero portion 208, all zero portion 212, and all zero portion 222 will comprise zero values in the parity check matrix 230.

As illustrated, the resulting syndrome 232 is divided into two portions: upper syndrome 224 and lower syndrome 226. The syndrome values of upper syndrome 224 are computed by computing the product of the codeword 228 and the upper matrix while the syndrome values of lower syndrome 226 are computed by computing the product of codeword 228 with the lower matrix. The use of all zero portions (e.g., all zero portion 208, all zero portion 212, and all zero portion 222) impacts what portions of the code word 228 will influence the syndrome 232. Specifically, due to all zero portion 208, any errors in the payload 202 will not impact the upper syndrome 224, further due to all zero portion 212, the upper syndrome will not be impacted by user data entries in the parity portion 206. Specifically, QK parity portion 214 may be associated with parity bits generated for the QK index 204 while parity check portion 220 may be associated with parity bits associated with the payload 202. As an example, if the parity portion 206 comprises the bits “010101,” the first three may be generated for the payload 202 while the final three may be generated for the QK index 204. The specific size of each is not limiting.

In the illustrated implementation, QK index upper 210 and QK index lower 218 may comprise parity check coefficients to check for errors within the QK index 204. Specifically, in some implementations, the generated QK index value may not be stored in persistent storage. By contrast, QK index 204 may be set to all zero values when a one-hot encoding is used. With this configuration, the QK index 204 will either contain no errors if no packets were inverted or will contain one error (the one-hot position of which packet was the last inverted packet). If an error occurs in payload 202, there may be two errors (one in QK index 204 and one in payload 202).

To accommodate the two-error scenario, the parity check matrix 230 must comply with two requirements. First, the matrix must be able to correct one error in the QK index bits and one in the payload bits. Second, the matrix must enable balancing according to the QK algorithm described in FIG. 1.

With respect to the first requirement, when an error is detected in both the payload and QK index, the resulting parity check matrix must distinguish this scenario from other errors in the payload and QK index bits, from any single error scenario, and from a no error syndrome.

The parity check matrix accomplishes this by ensuring that a simple signature in the syndrome 232 occurs when a QK inversion is made. This is caused by the use of all zero portion 208 which guarantees that the columns associated with the QK index in the parity check matrix are not all zeros in the upper matrix. The upper matrix is only impacted by an inversion (e.g., a non-zero QK index) and/or an error in the QK parity bits. In this manner, a simple syndrome signature can be obtained when the upper part of the syndrome is not all zeroes.

To decode a syndrome that occurs when an error exists in the QK parity portion and/or the QK index (referred to in the following paragraph as a “reference syndrome”), the possible syndrome values must be different from other possible values.

In general, there are four error cases that must be considered to ensure this difference. First, any reference syndrome must be different from any other syndrome generated when one error is in the QK parity portion while another error is in the QK index. This implies that the columns associated with the QK upper index 210 and QK lower index 218 must differ by at least three bits. Second, any reference syndrome must be different from any other single error occurring only in the QK parity portion 214. This implies that the columns associated with the QK upper index 210 and QK lower index 218 must contain at least three bits set to one. Third, any reference syndrome must be different from any other single error in the QK index 204. This implies that the columns associated with the QK upper index 210 and QK lower index 218 must contain at least two bits set to one. Fourth, any reference syndrome must be different from any other single error in payload 202. This implies that the columns associated with all zero portion 208 must be all zeroes.

As discussed above, the matrix must enable balancing according to the QK algorithm described in FIG. 1. Under this requirement, an exclusive OR (XOR) of the columns associated with composing a packet should all be zero and all bits of a message are include in the packets. The use of all zero portion 208 places additional constraints on the parity check matrix. According to the QK procedure, a given packet will contain two QK index bits and three additional bits (either payload bits or parity bits) given a packet size of five. If other packet sizes are used, two QK index bits will still be present, but the number of other bits may increase or decrease. Since all zero portion 208 is all zero, QK index upper 210 should be compensated only with QK parity bits from parity portion 206. Thus, each packet will include two QK index bits, one or more QK index parity bits, and user data bits. Thus, QK index parity bits will be used by multiple packets and may be inverted many times during the QK process to obtain a balanced message.

If QK parity bits are included within packets, this will increase the total number of packets of the codeword. Thus, in some implementations, the packets may be constructed in a specific manner. First, each packet may include two consecutive QK index bits. Second, the first QK index bit may be shared with a previous packet. Third, the column of the parity check matrix associated with the second QK index bit should be as similar as possible to the column of the first QK index bit. That is, the QK index list and order must be chosen to reduce the difference between consecutive QK index associated columns. In general, the Hamming distance between the columns of the two QK index bits into the same packet should be as low as possible. Further, in some implementations, if some bits are inverted multiple times through packets, this number of times should be odd to ensure that they retain the inverted value in the final inversion.

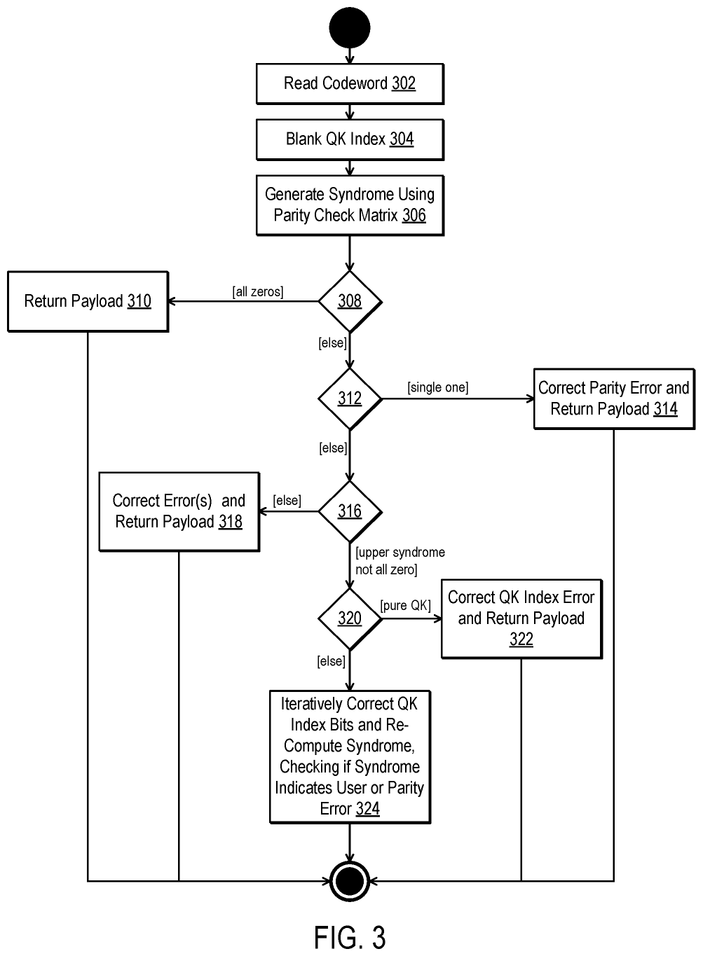

FIG. 3 is a flow diagram illustrating a method for decoding a codeword and processing a syndrome according to some of the disclosed embodiments.

In step 302, the method can include reading a codeword. In some implementations, the codeword may include a payload and a set of parity bits. In some implementations, the payload can comprise any type of user data. In some implementations, the parity bits can include parity bits generated using a generator matrix corresponding to the parity check matrix of FIG. 2. In some implementations, the value of the QK index is not stored in the memory device.

In step 304, the method can include generating a blank QK index value. In some implementations, the QK index value can be represented as a one-hot coding value. As such, the method can use a value of zero as the QK index value. Certainly, in some scenarios, this may be the proper QK index if no inversions of the payload were performed during writing. However, if any inversions were performed, the blanked value of zero will be incorrect. Since a one-hot encoding is used this will mean that the blanked QK index will include exactly one error. Thus, in step 304, either no errors are introduced into the codeword or exactly one error is introduced into the codeword. However, as will be discussed, errors may also occur in the payload, the parity bits associated with the payload, and the parity bits associated with the proper QK index.

In step 306, the method can include generating a syndrome using the parity check matrix described in FIG. 2. As discussed, the codeword (including QK index) can be input into the parity check matrix and products of the codeword and the parity check equations can be computed to output the syndrome. The syndrome will include an upper portion and lower portion. The upper portion can be computed by computing the product of the blanked QK index value with an QK index upper portion of the parity check matrix and computing the product of the QK parity bits with QK parity portion. Since all other portions of the matrix are all zeros, the upper syndrome is influenced only by the QK index and its corresponding parity. By contrast, the lower portion of the syndrome is computed by computing three products: one between the payload and the payload check portion, one between the QK index and QK index lower portion, and one between the payload and QK index parity bits and the parity check portion. As such, the lower syndrome is influenced by the payload and payload and QK index parity as well as the QK index itself. As with other ECC systems, the syndrome will comprise a one-dimensional vector representing errors in the codeword.

In step 308, the method can include first determining if the syndrome contains all zero values. If so, the method can determine that the codeword is valid and contains no errors. As such, in step 310, the method can return the payload. Since the blanked QK index is used, the method can presume no inversions were made during the QK procedure and thus no inversions are necessary before returning the payload.

In step 312, if the syndrome includes at least one non-zero value (i.e., one), the method can then count the number of non-zero values and first determine if exactly one non-zero value occurs. If so, the method proceeds to step 314. In step 314, the method can ascertain that the error has occurred in a parity bit (due to the constraints discussed above) and can correct the error using standard ECC1 correction power. After correcting the error, the method can include returning the payload.

By contrast, if more than one non-zero value appears in the syndrome, the method proceeds to step 316 where it determines whether the upper syndrome includes a non-zero value. If the method determines that the upper syndrome is all zero, the method can presume that no inversion was applied since the product of the QK index and the QK index upper portion is zero and the product of the QK parity and the QK parity portion is zero. Since a blanked QK index was used, this means that the blanked QK index (indicating no inversions) was valid. As such, any errors must occur within the user data or parity portion. Thus, in step 318, the method can correct the errors in the user data or parity portion and return the correct payload. As discussed, since an ECC1 may be used, step 318 may include correcting a single error in the user data.

By contrast, if the method determines that the upper syndrome is not all zeros, then the method proceeds to step 320 where it determines if the syndrome represents an error solely in the QK index (a “pure” QKI error).

As discussed above, such a determination can be ensured by the first constraint that the columns associated with the QKI upper index and QKI lower index differ by at least three bits. As such, the method can determine if at least one bit appears in the upper syndrome. If so, the method can ascertain that the user data is valid, and errors only occur in the QK index portion or the QK index itself. In this scenario, in step 322, the method can use the ECC correction power to correct the QK index value and/or parity bits and then return the payload. Since the QK index was blanked and an error was detected in the QK index area, this means that the actual QK index is non-zero. Thus, in some implementations, the method can further include performing QK inversions on the payload based on the corrected QK index to obtain the correct payload prior to returning the payload.

If, on the other hand, the error is not a pure QKI error, the method then proceeds to step 324 where the method attempts to correct the QK index one at a time and checks if the resulting syndrome is equal to a user data error or parity bit error.

In step 324, the method cannot ascertain if the syndrome is indicative of an error solely in the QK index, solely in the payload or parity, or both. Since the QK index was synthesized as a blanked value, the method can re-execute itself, synthesizing increasing QK index values and performing the above steps until the decisions until one of step 310, step 314, step 318, or step 322 are executed. For example, given a four-bit QK index, the method can re-execute setting the QK index to 0001, then to 0010, then to 0100, then to 1000. At least one of these permutations will clear the error on the QK index portion and expose whether any errors remain in the user data or parity portion of the codeword. Once the method exposes this error, it can correct the error using the ECC1 correction power and return the valid codeword.

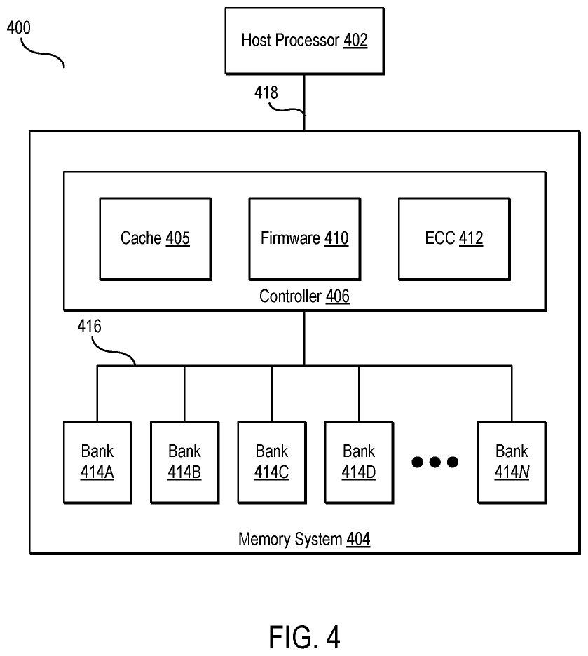

FIG. 4 is a block diagram illustrating a memory system according to some embodiments of the disclosure.

As illustrated in FIG. 4, a computing system 400 includes a host processor 402 communicatively coupled to a memory system 404 via a bus 418. The memory system 404 comprises a controller 406 communicatively coupled to one or more memory banks 414A-414N, forming a memory array via a bus/interface 416. As illustrated, controller 406 includes a local cache 405, firmware 410, and an error correction code (ECC) module 412.

In the illustrated embodiment, a host processor 402 can comprise any type of computer processor, e.g., a central processing unit (CPU), graphics processing unit (GPU), or other types of general-purpose or special-purpose computing devices. The host processor 402 includes one or more output ports that allow for the transmission of address, user, and control data between the host processor 402 and the memory system 404. In the illustrated embodiment, this communication is performed over the bus 418. In one embodiment, the bus 418 comprises an input/output (I/O) bus or a similar type of bus.

The memory system 404 is responsible for managing one or more memory banks 414A-414N. In one embodiment, the banks 414A-414N comprise NAND Flash dies or other configurations of non-volatile memory. In one embodiment, the memory banks 414A-414N comprise a memory array.

The banks 414A-414N are managed by the controller 406. In some embodiments, controller 406 comprises a computing device configured to mediate access to and from banks 414A-414N. In one embodiment, controller 406 comprises an ASIC or other circuitry installed on a printed circuit board housing the banks 414A-414N. In some embodiments, the controller 406 may be physically separate from the banks 414A-414N. Controller 406 communicates with the banks 414A-414N over interface 416. In some embodiments, this interface 416 comprises a physically wired (e.g., traced) interface. In other embodiments, the interface 416 comprises a standard bus for communicating with banks 414A-414N.

Controller 406 comprises various modules 405-412. In one embodiment, the various modules 405-412 comprise various physically distinct modules or circuits. In other embodiments, the modules 405-412 may completely (or partially) be implemented in software or firmware.

As illustrated, firmware 410 comprises the core of the controller and manages all operations of the controller 406. Firmware 410 may implement some or all the methods described above.

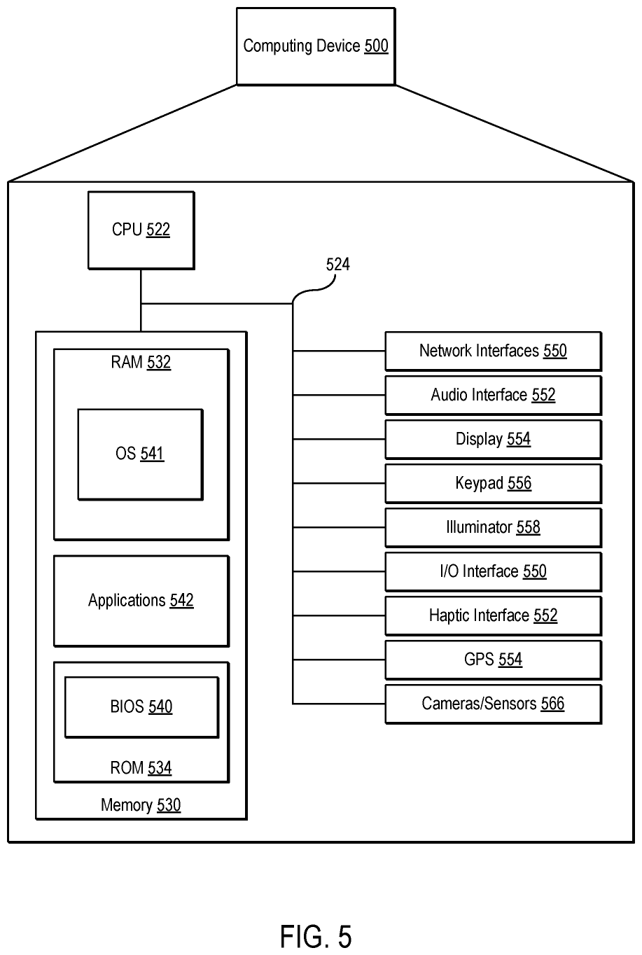

FIG. 5 is a block diagram illustrating a computing device showing an example of a client or server device used in the various embodiments of the disclosure.

The computing device 500 can include more or fewer components than those shown in FIG. 5, depending on the deployment or usage of the device 500. For example, a server computing device, such as a rack-mounted server, may not include audio interfaces 552, displays 554, keypads 556, illuminators 558, haptic interfaces 562, Global Positioning Service (GPS) receivers 564, or cameras/sensors 566. Some devices can include additional components not shown, such as graphics processing unit (GPU) devices, cryptographic co-processors, artificial intelligence (AI) accelerators, or other peripheral devices.

As shown in the figure, device 500 includes a central processing unit (CPU) 522 in communication with a mass memory 530 via a bus 524. The computing device 500 also includes one or more network interfaces 550, an audio interface 552, a display 554, a keypad 556, an illuminator 558, an input/output interface 560, a haptic interface 562, an optional global positioning systems (GPS) receiver 564 and a camera(s) or other optical, thermal, or electromagnetic sensors 566. Device 500 can include one camera/sensor 566 or a plurality of cameras/sensor 566. The positioning of the camera(s)/sensor(s) 566 on the device 500 can change per device 500 model, per device 500 capabilities, and the like, or some combination thereof.

In some embodiments, the CPU 522 can comprise a general-purpose CPU. The CPU 522 can comprise a single-core or multiple-core CPU. The CPU 522 can comprise a system-on-A-chip (SoC) or a similar embedded system. In some embodiments, a GPU can be used in place of, or in combination with, a CPU 522. Mass memory 530 can comprise a dynamic random-access memory (DRAM) device, a static random-access memory device (SRAM), or a Flash (e.g., NAND Flash) memory device. In some embodiments, mass memory 530 can comprise a combination of such memory types. In one embodiment, the bus 524 can comprise a Peripheral Component Interconnect Express (PCIe) bus. In some embodiments, the bus 524 can comprise multiple buses instead of a single bus.

Mass memory 530 illustrates another example of computer storage media for the storage of information such as computer-readable instructions, data structures, program modules, or other data. Mass memory 530 stores a basic input/output system (“BIOS”) 540 for controlling the low-level operation of the computing device 500. In the illustrated embodiment, the BIOS 540 may be stored in a read-only memory (ROM) such as ROM 534. The mass memory also stores an operating system 541 for controlling the operation of the computing device 500

Applications 542 can include computer-executable instructions which, when executed by the computing device 500, perform any of the methods (or portions of the methods) described previously in the description of the preceding figures. In some embodiments, the software or programs implementing the method embodiments can be read from a hard disk drive (not illustrated) and temporarily stored in RAM 532 by CPU 522. CPU 522 can then read the software or data from RAM 532, process them, and store them in RAM 532 again.

The computing device 500 can optionally communicate with a base station (not shown) or directly with another computing device. Network interface 550 is sometimes known as a transceiver, transceiving device, or network interface card (NIC).

The audio interface 552 produces and receives audio signals such as the sound of a human voice. For example, the audio interface 552 can be coupled to a speaker and microphone (not shown) to enable telecommunication with others or generate an audio acknowledgment for some action. Display 554 can be a liquid crystal display (LCD), gas plasma, light-emitting diode (LED), or any other type of display used with a computing device. Display 554 can also include a touch-sensitive screen arranged to receive input from an object such as a stylus or a digit from a human hand.

Keypad 556 can comprise any input device arranged to receive input from a user. Illuminator 558 can provide a status indication or provide light.

The computing device 500 also comprises an input/output interface 560 for communicating with external devices, using communication technologies, such as USB, infrared, Bluetooth®, or the like. The haptic interface 562 provides tactile feedback to a user of the client device.

The optional GPS receiver 564 can determine the physical coordinates of the computing device 500 on the surface of the Earth, which typically outputs a location as latitude and longitude values. GPS receiver 564 can also employ other geo-positioning mechanisms, including, but not limited to, triangulation, assisted GPS (AGPS), E-OTD, CI, SAI, ETA, BSS, or the like, to further determine the physical location of the computing device 500 on the surface of the Earth. In one embodiment, however, the computing device 500 can communicate through other components, providing other information that can be employed to determine the physical location of the device, including, for example, a MAC address, IP address, or the like.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to the desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product or software that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as read-only memory (“ROM”), random access memory (“RAM”), magnetic disk storage media, optical storage media, flash memory components, etc.

In this description, various functions and operations are described as being performed by or caused by computer instructions to simplify the description. However, those skilled in the art will recognize what is meant by such expressions is that the functions result from the execution of the computer instructions by one or more controllers or processors, such as a microprocessor. Alternatively, or in combination, the functions and operations can be implemented using special-purpose circuitry, with or without software instructions, such as using Application-Specific Integrated Circuit (ASIC) or Field-Programmable Gate Array (FPGA). Embodiments can be implemented using hardwired circuitry without software instructions or in combination with software instructions. Thus, the techniques are limited neither to any specific combination of hardware circuitry and software nor to any particular source for the instructions executed by the data processing system.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

We claim:

1. A method comprising:
receiving an error code correction (ECC) matrix; and
extending the ECC matrix to form an extended matrix that includes an all zero portion, a portion for checking a quantized Knuth (QK) index, and a portion for checking a parity of the QK index.

2. The method of claim 1, wherein the all zero portion includes three all zero portions, wherein a first all zero portion and a second all zero portion are included in an upper matrix of the extended matrix and a third all zero portion is included in a lower matrix of the extended matrix.

3. The method of claim 2, wherein the portion for checking a QK index includes an upper portion for checking the QK index in the upper matrix and a lower portion for checking the QK index in the lower matrix.

4. The method of claim 3, wherein the portion for checking a parity of the QK index is included in the upper matrix.

5. The method of claim 4, wherein the extended matrix is of the form:
$$[ \begin{matrix}All {0}_{1} & QKU & All {0}_{2} & QKP \\ UD & QKL & UDP & All {0}_{3}\end{matrix} ] ,$$
where
All0₁ represents the first all zero portion, All0₂ represents the second all zero portion, All0₃ represents the third all zero portion, QKU represents the upper portion for checking the QK index, QKL represents the lower portion for checking the QK index, QKP represents the portion for checking a parity of the QK index, UD represents a portion for checking a payload and UDP represents a portion for checking a parity of the payload and the QK index.

6. The method of claim 1, further comprising inputting a codeword into the extended matrix to generate a syndrome, the codeword including user data, a QK index, and parity bits, the syndrome including an upper portion generated based on the QK index and parity bits associated with the QK index and a lower portion generated using the user data, the QK index, and parity bits associated with the user data.

7. A method comprising:
inserting a codeword into a parity check matrix to obtain an upper syndrome and a lower syndrome, the codeword including a payload, a quantized Knuth (QK) index, and parity bits;
updating the QK index to generate new codewords;
inserting the new codewords into the parity check matrix until an error is detected only in the payload or in a portion of the parity bits associated with the payload;
correcting the error;
inverting packets of the payload based on the corrected QK index; and
returning a corrected payload.

8. The method of claim 7, further comprising generating the QK index by generating an all-zero value.

9. The method of claim 7, wherein the QK index comprises a one-hot encoded packet position relative to a number of packets that were inverted.

10. The method of claim 9, wherein the inverted packets include parity bits and QK index bits.

11. The method of claim 7, wherein determining, based on the upper syndrome and lower syndrome, that an error is present in the QK index comprises:
determining that the syndrome includes multiple non-zero values;
determining that the upper syndrome contains non-zero values; and
determining that the error is not solely in the QK index.

12. The method of claim 7, wherein iteratively updating the QK index to generate new codewords comprises iterating through a series of one-hot encoded values starting at one.

13. The method of claim 7, wherein determining that an error is only in the payload or in a portion of the parity bits associated with the payload comprises determining that the upper syndrome contains all zeros.

14. A method comprising:
receiving a payload and a parity portion;
generating a first quantized Knuth (QK) index;
adding the QK index to the payload and parity portion to generate a codeword;
inserting the codeword into a parity check matrix to generate an upper syndrome and lower syndrome; and
correcting the codeword based on the upper syndrome and lower syndrome.

15. The method of claim 14, wherein correcting the codeword based on contents of the upper syndrome and lower syndrome comprises determining that the syndrome contain all zeros and returning the codeword.

16. The method of claim 14, wherein correcting the codeword based on contents of the upper syndrome and lower syndrome comprises determining that the syndrome contains a single non-zero value, correcting an error in the parity portion using an ECC1 engine, and returning a corrected payload.

17. The method of claim 14, wherein correcting the codeword based on contents of the upper syndrome and lower syndrome comprises determining that the syndrome includes multiple non-zero values and that the upper syndrome contains all zero values and correcting one or more errors in the payload or parity portion and returning a corrected payload.

18. The method of claim 14, wherein correcting the codeword based on contents of the upper syndrome and lower syndrome comprises determining that the syndrome includes multiple non-zero values and that the upper syndrome contains the non-zero values, correcting an error in the QK index to obtain a corrected QK index, inverting a subset of the codeword based on the corrected QK index, and returning a corrected payload.

19. The method of claim 14, wherein correcting the codeword based on contents of the upper syndrome and lower syndrome comprises determining that the syndrome includes multiple non-zero values, that the lower syndrome contains at least one non-zero value, and the upper syndrome contains at least one non-zero value and iteratively updating the QK index to generate new codewords.

20. The method of claim 19, further comprising:
inserting the new codewords into the parity check matrix until an error is detected only in the payload or bits of the parity portion associated with the payload;
correcting the error; and
returning a corrected payload.
